(19) United States
(12) Patent Application Publication
(10) Pub. No.: US 2016/0148980 A1
(43) Pub. Date: May 26, 2016

(54) ORGANIC X-RAY DETECTORS AND RELATED SYSTEMS

(71) Applicant: General Electric Company, Schenectady, NY (US)

(72) Inventors: Jie Jerry Liu, Niskayuna, NY (US); Kwang Hyup An, Rexford, NY (US)

(21) Appl. No.: 14/549,989

(22) Filed: Nov. 21, 2014

(51) Int. Cl. H01L 27/30; G01N 23/04; H01L 51/00

(52) U.S. Cl. CPC H01L 27/308; H01L 27/307; H01L 51/0007; G01N 23/04; H01L 51/0043; H01L 51/0038; H01L 51/0039; H01L 51/0035; H01L 51/0046; H01L 51/0036; H01L 51/0059; H01L 51/006; H01L 51/0058

(57) ABSTRACT

Organic x-ray detectors and organic x-ray systems employing the detectors are presented. An Organic x-ray detector has a layered structure that includes a thin film transistor (TFT) array disposed on a substrate, a first electrode disposed on the TFT array, a leakage reduction layer disposed on the first electrode, an absorber layer disposed on the leakage reduction layer, a second electrode disposed on the absorber layer; and a scintillator layer disposed on the second electrode. The leakage reduction layer includes a conjugate polymer and a crosslinkable compound. A process for fabricating an organic x-ray detector is also presented.

### BACKGROUND

Embodiments of the invention generally relate to organic x-ray detectors including organic photodiodes. More particularly, embodiments of the invention relate to organic x-ray detectors including multilayered structures having leakage reduction layers.

Digital x-ray detectors fabricated with continuous photodiodes have potential applications for low cost digital radiography as well as for rugged, light-weight and portable detectors. Digital x-ray detectors with continuous photodiodes have an increased fill factor and potentially higher quantum efficiency. The continuous photodiode generally includes organic photodiodes (OPDs).

Single-layered OPDs are attractive because of their good efficiency, simplified device structure and potentially low manufacturing cost. However, the single-layered OPDs generally have high dark leakage currents that create noise and limit the reliability of the device. One approach for reducing the dark leakage current is to incorporate one or two blocking layers that separate the active absorber from one or both electrodes. Fullerenes, polyvinylcarbazoles, and polystyrene-amine copolymer are some of the materials that have been used in these layers. However, the fabrication of a multilayered device comprising organic materials has been problematic using methods involving solvents. This is because of dissolution of underlying layers in solutions employed for disposing the succeeding layers.

It may therefore be desirable to provide multilayered structures of organic x-ray detectors, and methods of fabricating the organic x-ray detectors.

### BRIEF DESCRIPTION

In one aspect, the invention relates to organic x-ray detectors and x-ray imaging systems employing the detectors. Organic x-ray detectors according to the present invention have a layered structure that includes a thin film transistor (TFT) array disposed on a substrate, a first electrode disposed on the TFT array, a leakage reduction layer disposed on the first electrode, an absorber layer disposed on the leakage reduction layer, a second electrode disposed on the absorber layer; and a scintillator layer disposed on the second electrode. The leakage reduction layer includes a conjugate polymer and a crosslinkable compound.

In another aspect, the invention relates to a process for fabricating an organic x-ray detector. The process includes disposing a leakage reduction layer comprising a conjugate polymer and a crosslinkable compound on a first electrode of the TFT substrate; disposing an absorber layer from a solution of an accepter material and a donor material with a first solvent selected from chlorobenzene, dichlorobenzene or a mixture thereof; disposing a second electrode on the absorber layer; and disposing a scintillator layer on the second electrode.

### DRAWINGS

These and other features, aspects, and advantages of the present invention will become better understood when the following detailed description is read with reference to the accompanying drawings in which like characters represent like parts throughout the drawings, wherein:

FIG. 1 is a schematic of a layered structure of an organic x-ray detector, according to one embodiment of the present invention;

FIG. 2 is a schematic of a layered structure of an organic x-ray detector, according to another embodiment of the present invention;

FIG. 3 is a schematic diagram of energy levels of materials for a layered structure of an organic x-ray detector according to one embodiment of the present invention;

FIG. 4 is a schematic of an x-ray imaging system including an organic x-ray detector according to one embodiment of the present invention;

FIG. 5 is a schematic of an x-ray imaging system including an organic x-ray detector according to one embodiment of the present invention;

FIG. 6 is a schematic of an x-ray imaging system including an organic x-ray detector according to one embodiment of the present invention.

### DETAILED DESCRIPTION

In the following specification and the claims, which follow, reference will be made to a number of terms, which shall be defined to have the following meanings. The singular forms “a”, “an” and “the” include plural referents unless the context clearly dictates otherwise. “Optional” or “optionally” means that the subsequently described event or circumstance may or may not occur, and that the description includes instances where the event occurs and instances where it does not. As used herein, the term “and/or” includes any and all combinations of one or more of the associated listed items.

Unless defined otherwise, technical and scientific terms used herein have the same meaning as is commonly understood by one of skill in the art to which this invention belongs. The terms “first”, “second”, and the like, as used herein do not denote any order, quantity, or importance, but rather are used to distinguish one element from another. In the present disclosure, when a layer is being described as “disposed on” another layer or substrate, it is to be understood that the layers can either be directly contacting each other or have one (or more) layer or feature therebetween, unless otherwise specifically indicated. Further, the term “on” describes the relative position of the layers to each other and does not necessarily mean “on top of” since the relative position above or below depends upon the orientation of the device to the viewer.

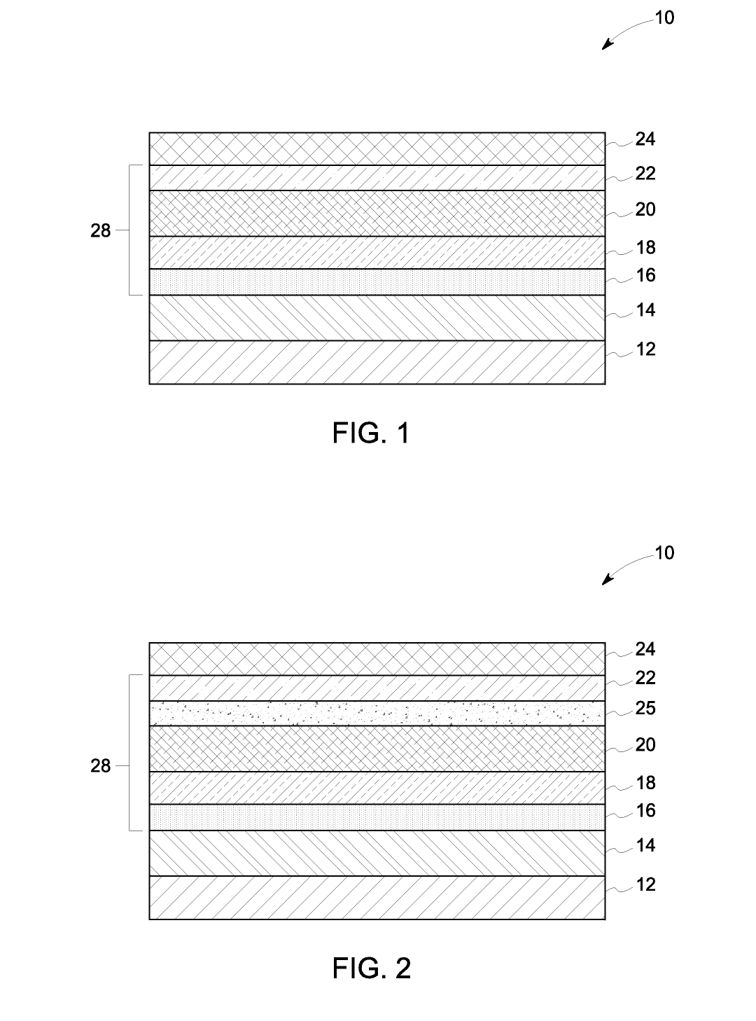

FIG. 1 schematically illustrates a layered structure of an organic x-ray detector 10 according to some embodiments of the present invention, in which a thin film transistor (TFT) array 14 is disposed on substrate 12, a first electrode 16 is disposed on the TFT array 14, a leakage reduction layer 18 is disposed on the first electrode 16, an absorber layer 20 is disposed on the leakage reduction layer 18, a second electrode 22 is disposed on the absorber layer 20, and a scintillator layer 24 is disposed on the second electrode 22. The combination of the first electrode 16, the TFT array 14 and the substrate 12 is also referred to as a TFT substrate, which may be fabricated separately from the other layers, or obtained from a commercial vendor.

In some embodiments, the second electrode 22 functions as the cathode and the first electrode 16 as the anode and the leakage reduction layer 18 is an electron blocking layer. The first electrode 16, the leakage reduction layer 18, the absorber layer 20 and the second electrode 22, in combination, form a photodiode 28.

The substrate 12 may be composed of a rigid or flexible material. Suitable substrate materials include glass, ceramic, plastic and metals. The substrate 12 may be present as a rigid sheet such as a thick glass, a thick plastic sheet, a thick plastic composite sheet, and a metal plate; or a flexible sheet, such as, a thin glass sheet, a thin plastic sheet, a thin plastic composite sheet, and metal foil. Examples of suitable materials for the substrate include glass, which may be rigid or flexible, plastics such as polyethylene terephthalate, polybutylene phthalate, polyethylene naphthalate, polystyrene, polycarbonate, polyether sulfone, polyallylate, polyimide, polycycloolefin, norbornene resins, and fluoropolymers, metals such as stainless steel, aluminum, silver and gold, metal oxides, such as titanium oxide and zinc oxide, and semiconductors such as silicon. Combinations of materials may also be used. In some embodiments, the substrate includes a polycarbonate.

By using an unbreakable material instead of a fragile glass substrate for the x-ray detector, the components and materials designed to absorb bending stress or drop shock can be reduced in size and weight or eliminated, and the overall weight and thickness of the detector can be reduced. Removing costly materials which are used to protect the glass substrate decreases the overall cost of the detector. In addition, the number of patterned layers needed for the detector can be reduced by utilizing an un-patterned low cost organic photodiode.

The thin film transistor (TFT) array 14 is a two dimensional array of passive or active pixels which store charge for read out by electronics, disposed on an active layer formed of amorphous silicon or an amorphous metal oxide, or organic semiconductors. In some embodiments, the TFT array 14 includes a silicon TFT array, an oxide TFT array, an organic TFT, or combinations thereof. Suitable amorphous metal oxides include zinc oxide, zinc tin oxide, indium oxides, indium zinc oxides (In—Zn—O series), indium gallium oxides, gallium zinc oxides, indium silicon zinc oxides, and indium gallium zinc oxides (IGZO). IGZO materials include InGaO₃(ZnO)ₘ, where m<6, and InGaZnO₄. Suitable organic semiconductors include, but are not limited to, conjugated aromatic materials, such as rubrene, tetracene, pentacene, perylenediimides, tetracyanoquinodimethane and polymeric materials such as polythiophenes, polybenzodithiophenes, polyfluorene, polydiacetylene, poly(2,5-thiophenylene vinylene) and poly(p-phenylene vinylene) and derivatives thereof.

The layered structure 10 of the organic x-ray detector further includes at least one leakage reduction layer 18 that forms a barrier to dark leakage current when the diode is reverse biased. The leakage reduction layer may be a continuous patterned or unpatterned conductive layer; in some embodiments, completely covering the first electrode 16. A range of materials satisfying the HOMO/LUMO/mobility requirements may be used for the leakage reduction layer 18. According to some embodiments of the invention, the leakage reduction layer 18 includes a conjugate polymer and a crosslinkable compound. The conjugate polymer includes, but not limited to, a polytriarylamine. Other suitable examples of conjugate polymers include a poly(para-phenylene), a poly(N-vinylcarbazole), a polyfluorene, a poly(p-phynylene vinylene), copolymers thereof, or a combination thereof. In some embodiments, the polytriarylamine comprises structural unit of formula I

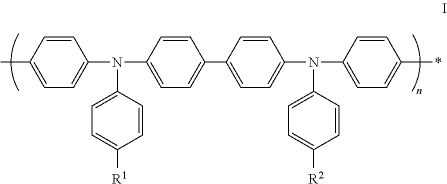

wherein R¹ and R² are, independently, a C₁-C₂₀ aliphatic radical, a C₃-C₂₀ aromatic radical, or C₃-C₂₀ cycloaliphatic radical.

In some embodiments, the polytriarylamine comprises poly-TPD (poly(N,N′-bis(4-butylphenyl)-N,N′-bis(phenyl)-benzidine).

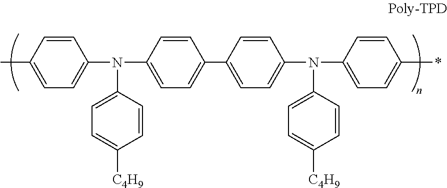

In some embodiments, the conjugate polymer comprises PCDTBT: Poly[N-9′-heptadecanyl-2,7-carbazole-alt-5,5-(4′,7′-di-2-thienyl-2′,1′,3′-benzothiadiazole)]

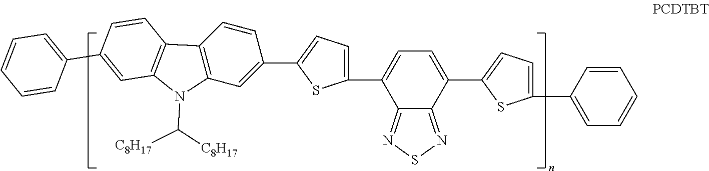

As noted, the leakage reduction layer 18 further comprises a crosslinkable compound. In some embodiments, the crosslinkable compound includes an epoxy. In some embodiments, the crosslinkable compound comprises at least one functional group selected from arylamine and arylphosphine, and at least two functional groups selected from vinyl, allyl, vinyl ether, epoxy and acrylate. In some embodiments, the crosslinkable compound is of formula II

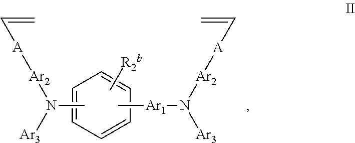

wherein,

Ar₁ is a direct bond, an aryl or heteroaryl;

Ar₂ and Ar₃ are independently at each occurrence, an aryl or heteroaryl; and

A is independently at each occurrence, O or a direct bond

R₂ is a C₁-C₂₀ aliphatic radical, a C₃-C₂₀ aromatic radical, or a C₃-C₂₀ cycloaliphatic radical; and b is an integer ranging from 0-4.

In some embodiments, the crosslinkable compound is selected from:

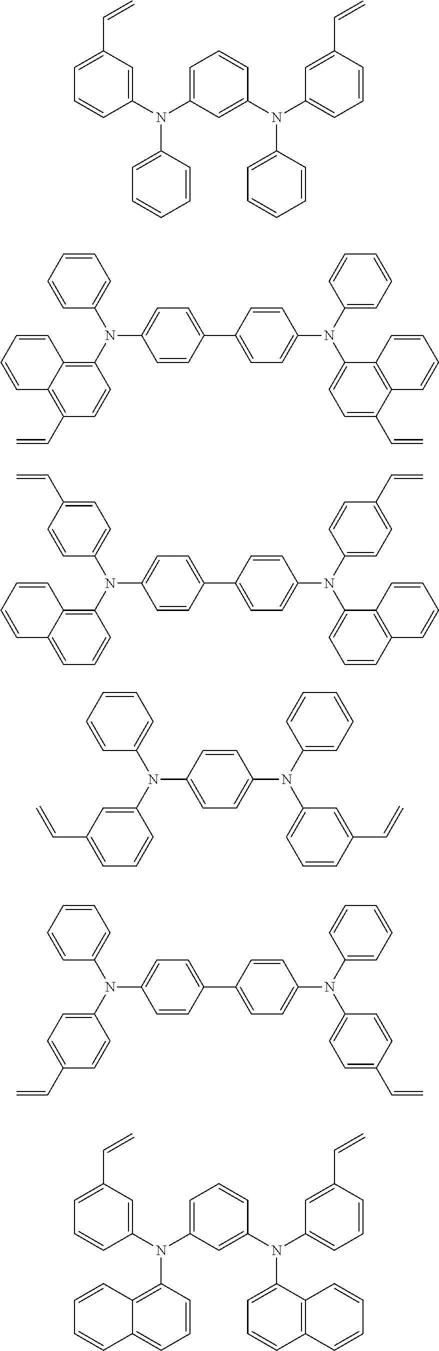

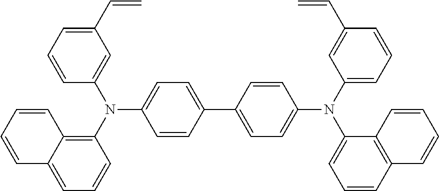 [SMILES: C=Cc1cccc(N(c2ccc(-c3ccc(N(c4cccc(C=C)c4)c4cccc5ccccc45)cc3)cc2)c2cccc3ccccc23)c1]

In some embodiments, the conjugate polymer and the crosslinkable compound are in about 1:1 in weight ratio in the leakage reduction layer 18.

Depending on the variations in design, the organic photodiode 28 may include a single absorber layer or may include multiple absorber layers. The organic absorber layer may be a bulk, hetero-junction organic photodiode layer that absorbs light, separates charge and transports holes and electrons to the contact layers. In some embodiments, the absorber layer may be patterned. Absorber layer may include a blend of a donor material and an acceptor material. Further, the HOMO/LUMO levels of the donor and acceptor materials may be compatible with that of the other layers of the layered structure, e.g., the leakage reduction layer, the first and second electrodes, in order to allow efficient charge extraction without creating an energetic barrier.

In some embodiments, the absorber layer 20 may be composed of a blend of a donor material and an acceptor material; more than one donor or acceptor may be included in the blend. In some embodiments, the donor and acceptor may be incorporated in the same molecule. Suitable donor materials are low bandgap polymers having LUMO ranging from about 1.9 eV to about 4.9 eV, particularly from 2.5 eV to 4.5 eV, more particularly from 3.0 eV to 4.5 eV; and HOMO ranging from about 2.9 eV to about 7 eV, particularly from 4.0 eV to 6 eV, more particularly from 4.5 eV to 6 eV. The low band gap polymers are conjugated polymers and copolymers composed of units derived from substituted or unsubstituted monoheterocyclic and polyheterocyclic monomers such as thiophene, fluorene, phenylenvinylene, carbazole, pyrrolopyrrole, and fused heteropolycyclic monomers containing the thiophene ring, including, but not limited to, thienothiophene, benzodithiophene, benzothiadiazole, pyrrolothiophene monomers, and substituted analogs thereof. In particular embodiments, the low band gap polymers comprise units derived from substituted or unsubstituted thienothiophene, benzodithiophene, benzothiadiazole, carbazole, isothianaphthene, pyrrole, benzo-bis(thiadiazole), thienopyrazine, fluorene, thiadiazolequinoxaline, or combinations thereof. In the context of the low band gap polymers described herein, the term “units derived from” means that the units are each a residue comprising the monoheterocyclic and polyheterocyclic group, without regard to the substituents present before or during the polymerization; for example, “the low band gap polymers comprise units derived from thienothiophene” means that the low band gap polymers comprise divalent thienothiophenyl groups. Examples of suitable materials for use as low bandgap polymers in the organic x-ray detectors according to the present invention include copolymers derived from substituted or unsubstituted thienothiophene, benzodithiophene, benzothiadiazole or carbazole monomers, and combinations thereof, such as poly[[4,8-bis[(2-ethyl hexyl)oxy]benzo[1,2-b:4,5-b′]dithiophene-2,6-diyl][3-fluoro-2-[(2-ethylhexyl)carbonyl]thieno[3,4-b]thiophenediyl (PTB7), 2,1,3-benzothiadiazole-4,7-diyl[4,4-bis(2-ethylhexyl)-4H-cyclopenta[2,1-b:3,4-b′]dithiophene-2,6-diyl (PCPDTBT), poly[[9-(1-octylnonyl)-9H-carbazole-2,7-diyl]-2,5-thiophenediyl-2,1,3-benzothiadiazole-4,7-diyl-2,5-thiophenediyl] (PCDTBT), poly[(4,40-bis(2-ethylhexyl)dithieno [3,2-b:20,30-d]silole)-2,6-diyl-alt-(2,1,3-benzo-thiadiazole)-4,7-diyl] (PSBTBT), poly((4,8-bis(octyloxy)benzo(1,2-b:4,5-b′)dithiophene-2,6-diyl)(2-((dodecyloxy)carbonyl) thieno(3,4-b)thiophenediyl)) (PTB1), poly((4,8-bis(octyloxy)benzo(1,2-b:4,5-b′)dithiophene-2,6-diyl)(2-((ethylhexyloxy)carbonyl) thieno(3,4-b)thiophenediyl)) (PTB2), poly((4,8-bis(octyl)benzo(1,2-b:4,5-b′)dithiophene-2,6-diyl) (2-((ethylhexyloxy)carbonyl) thieno(3,4-b)thiophenediyl)) (PTB3), poly((4,8-bis-(ethylhexyloxybenzo(1,2-b:4,5-b′)dithiophene-2,6-diyl)(2-((octyloxy)carbonyl)-3-fluoro)thieno(3,4-b)thiophenediyl)) (PTB4), poly((4,8-bis-(ethylhexyloxybenzo(1,2-b:4,5-b′)dithiophene-2,6-diyl)(2-((octyloxy)carbonyl) thieno(3,4-b)thiophenediyl)) (PTB5), poly((4,8-bis(octyloxy)benzo(1,2-b:4,5-b′)dithiophene-2,6-diyl)(2-((butyloctyloxy)carbonyl) thieno(3,4-b)thiophenediyl))(PTB 6), poly[[5-(2-ethylhexyl)-5,6-dihydro-4,6-dioxo-4H-thieno[3,4-c]pyrrole-1,3-diyl][4,8-bis[(2- ethylhexyl)oxy]benzo [1,2-b:4,5-b′]dithiophene-2,6-diyl]] (PBDTTPD), poly[1-(6-{4,8-bis[(2-ethylhexyl)oxy]-6-methylbenzo[1,2-b:4,5-b′]dithiophen-2-yl}-3-fluoro-4-methylthieno[3,4-b]thiophen- 2-yl)-1-octanone] (PBDTTT-CF), and poly[2,1,3-benzothiadiazole-4,7-diyl-2,5-thiophenediyl (9,9-dioctyl-9H-9-silafluorene-2,7-diyl)-2,5-thiophenediyl] (PSiF-DBT). Other suitable materials are poly[5,7-bis(4-decanyl-2-thienyl)thieno[3,4-b]diathiazole-thiophene-2,5] (PDDTT), poly[2,3-bis(4-(2-ethylhexyloxy)phenyl)-5,7-di(thiophen-2-yl)thieno[3,4-b]pyrazine] (PDTTP), and polythieno[3,4-b]thiophene (PTT). In some embodiments, the donor material is a conjugate polymer that is used in the leakage reduction layer 18. In particular embodiments, suitable materials are copolymers derived from substituted or unsubstituted benzodithiophene monomers, such as the PTB1-7 series and PCPDTBT; or benzothiadiazole monomers, such as PCDTBT and PCPDTBT. In particular embodiments, the donor material is a polymer with a low degree of crystallinity or is an amorphous polymer. Degree of crystallinity may be increased by substituting aromatic rings of the main polymer chain. Long chain alkyl groups containing six or more carbons or bulky polyhedral oligosilsesquioxane (POSS) may result in a polymer material with a lower degree of crystallinity than a polymer having no substituents on the aromatic ring, or having short chain substituents such as methyl groups. Degree of crystallinity may also be influenced by processing conditions and means, including, but not limited to, the solvents used to process the material and thermal annealing conditions. Degree of crystallinity is readily determined using analytical techniques such as calorimetry, differential scanning calorimetry, x-ray diffraction, infrared spectroscopy and polarized light microscopy.

Suitable materials for the acceptor include fullerene derivatives such as [6,6]-phenyl-C₆₁-butyric acid methyl ester (PCBM), PCBM analogs such as PC₇₀BM, PC71BM, PC₈₀BM, bis-adducts thereof, such as bis-PC₇₁BM, indene mono-adducts thereof, such as indene-C₆₀ monoadduct (ICMA) and indene bis-adducts thereof, such as indene-C₆₀ bisadduct (ICBA). Fluorine copolymers such as poly[(9,9-dioctylfluorenyl-2,7-diyl)-alt-(4,7-bis(3-hexylthiophen-5-yl)-2,1,3-benzothiadiazole)-2′,2″-diyl] (F8TBT) may also be used, alone or with a fullerene derivative.

An additional leakage reduction layer 25 may be disposed between the absorber layer 20 and the second electrode 22, as illustrated in FIG. 2. In some embodiments, the additional leakage reduction layer 25 is a hole blocking layer (HBL). Suitable materials for the hole blocking layer include phenanthroline compounds, for example, 2,9-dimethyl-4,7-diphenyl-1,10-phenanthroline (BCP), 4-biphenyloxolate aluminum(III) bis (2-methyl-8-quinolinato)-4-phenylphenolate (BAlq), 2,4-diphenyl-6-(49-triphenylsilanyl-biphenyl-4-yl)-1,3,5-triazine (DTBT), C60, (4,4′-N,N′-dicarbazole)biphenyl (CBP), as well as a range of metal oxides, such as TiO₂, ZnO, Ta₂O₅, and ZrO₂.

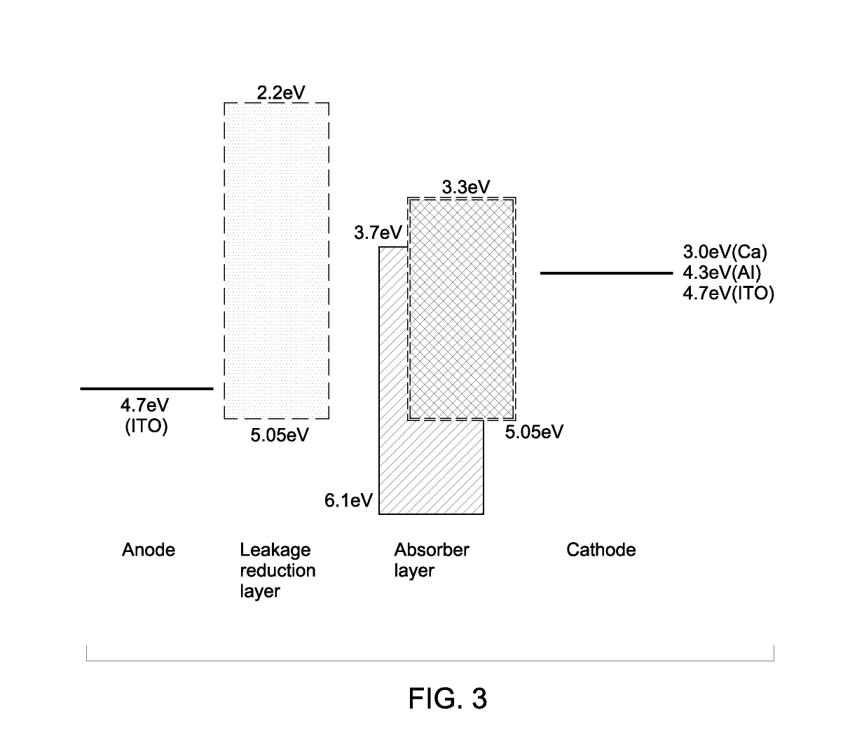

FIG. 3 is an energy level diagram for one embodiment of an organic x-ray detector comprising an anode electrode, a leakage reduction layer disposed between an absorber layer and the anode, and a cathode electrode. For efficient extraction with high quantum efficiency and low dark current, the following orientation of energy levels may be used. To reduce dark current due to electron leakage, the LUMO of the leakage reduction layer should be less than the LUMO of the acceptor, that is, closer to the vacuum level than the LUMO of the acceptor. To improve extraction of holes and hence the external quantum efficiency (EQE) of the device, the HOMO of the leakage reduction layer (i.e., the electron blocking layer) should be the same or less than the HOMO of the donor, that is, closer to the vacuum level than the HOMO of the donor. For efficient extraction of electrons, the LUMO of the HBL should be the same or greater than the LUMO of the acceptor, that is, further from the vacuum level than the acceptor. In addition, mid-gap defect states can offer a pathway for extraction of electrons to the cathode. To prevent dark current due to holes, the HOMO of the HBL should be greater than the HOMO of the donor.

The second electrode 22 is a semi-transparent conductive layer with compatible energy levels to allow extraction of charges without a barrier to extraction; transparent at the wavelength of emissions from the scintillator layer 24, particularly high in the transmission to visible light and low in resistance value. In one embodiment, the second electrode 22 functions as the cathode and the first electrode 16 as the anode and the leakage reduction layer 18 is the electron blocking layer. Suitable anode materials include, but are not limited to, metals such as Al, Ag, Au, and Pt, metal oxides such as ITO, IZO, and ZO, and organic conductors such as p-doped conjugated polymers like PEDOT. Suitable cathode materials include transparent conductive oxides (TCO) and thin films of metals such as gold and silver. Examples of suitable TCO include ITO, IZO, AZO, FTO, SnO₂, TiO₂, ZnO, indium zinc oxides (In—Zn—O series), indium gallum oxides, gallium zinc oxides, indium silicon zinc oxides, and IGZO. In many embodiments, ITO is used because of its low resistance and transparency. The first electrode 16 may be formed as one layer over an entire pixel portion or may be divided forming a lateral offset and/or vertical offset between the electrode and the data readout lines to reduce electronic noise that may result from capacitive coupling between the electrode of the photosensor control and a data readout line of the TFT array as described in copending U.S. Ser. No. 13/728,052, filed on Dec. 27, 2012, incorporated herein by reference.

The scintillator layer 24 is composed of a phosphor material that is capable of converting x-rays to visible light. The wavelength region of light emitted by scintillator 24 ranges from about 360 nm to about 830 nm. Suitable materials for the layer include, but are not limited to, cesium iodide (CsI), CsI (Tl) (cesium iodide to which thallium has been added) and terbium-activated gadolinium oxysulfide (GOS). Such materials are commercially available in the form of a sheet or screen. The scintillator layer 24 may include an adhesive layer (not shown) disposed on second electrode 22 for attaching a scintillator sheet.

Some embodiments provide processes for fabricating an organic x-ray detector. Referring to FIG. 1, a process includes disposing a leakage reduction layer 18 on a patterned first electrode 16 of a TFT substrate, disposing an absorber layer 20 on the leakage reduction layer 18, disposing an electrode layer 22 on the absorber layer 20, and disposing a scintillator layer 24 on the electrode layer 22. In some embodiments, the leakage reduction layer 18 is disposed on the first electrode 16 prior to the step of disposing the absorber layer 20.

Typically, the materials used in several layers of the organic photodiode may be soluble in the solutions used in forming subsequent layers of the diode, particularly, by using solution processes. For example, when a layer composed of a conjugate polymer is disposed prior to the absorber layer; a significant thickness of the layer may be washed out during the deposition of the absorber layer because the conjugate polymer may be soluble to the solvents typically used (e.g., chlorobenzene and dichlorobenzene) to process the absorber layer.

As noted previously, according to the embodiments of the invention, a crosslinkable compound in combination with a conjugate polymer may be used for the leakage reduction layer. In some embodiments, a mixture of the conjugate polymer and the crosslinkable compound may be prepared in a second solvent, for example chlorobenzene; and a layer may be deposited by any suitable deposition technique, such as spin coating. The crosslinkale compound is then cross-linked before the absorber layer is coated thereon in order to prevent dissolution (i.e., wash-out) of the conjugate polymer. The crosslinkable compound can be cross-linked thermally, by exposure to radiation or both thermally and by exposure to radiation. A variety of radiation sources, for example visible light sources, ultra-violet (UV) light sources, x-ray radiation sources, gamma radiation sources, or electron beam sources can be used for the purpose. The crosslinking process may be designed to prevent substrate deformation or device damage when a polymer material is used as a substrate, and curing temperature and time are typically dependent on the particular materials used. In one example, a layer composed of a polyamine in a device containing a plastic substrate may be cured at a temperature up to about 180° C. for about 1-2 hours. In another example, a layer composed of a polyamine in a device containing a plastic substrate may be cured by a hybrid approach involving both UV radiation and heat. For instance, UV radiation can be applied to the film while the film is being baked at a temperature up to about 180° C. That is the leakage reduction layer is fabricated at low temperatures compatible with plastic substrates. Thus, the present invention advantageously enables fabrication of layered structures of organic x-ray detectors on plastic substrates.

After the curing cycle, the absorber layer 20 may be coated on the leakage reduction layer 18 from a coating solution without damage to the leakage reduction layer. The coating solution for the deposition of the absorber layer may be prepared by solubilizing both an acceptor material and a donor material in a first solvent. Suitable solvents solubilize both donor and acceptor materials over a range of concentrations, and yield desired film microstructures and thicknesses. Examples include, but are not limited to, 1,2-dichlorobenzene, chlorobenzene, xylenes, methyl-naphthalene, and combinations thereof. Any suitable solution based deposition technique can be used. Suitable techniques include solvent casting, spin coating, dip coating, spray coating, and blade coating. The absorber layer may be crosslinked in order to reduce solubility of the donor material; crosslinking may be initiated thermally or by exposure to radiation.

Following solution coating of the organic photo detector, a second electrode 22 is deposited onto its surface by means such as thermal evaporation, sputtering and direct printing etc. Where a hole blocking layer is disposed on the absorber layer prior to the step of disposing the second electrode layer, the electrode is disposed directly on the hole blocking layer, by sputtering or any other suitable method, including wet coating processes. The scintillator layer is then disposed on the electrode. In many embodiments, the scintillator is present in the form of a screen or film, where the scintillator material is dispersed in a polymer film, and may be attached to the cathode via a pressure sensitive adhesive. Product electronics may then be bonded to the detector, and assembled into a product enclosure.

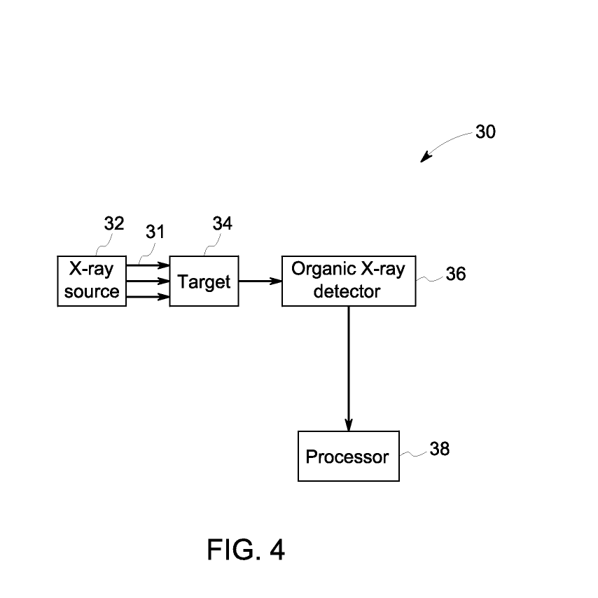

FIG. 4 shows an embodiment of an x-ray imaging system 30 according to the present invention, which may be designed to acquire and process X-ray image data. The system 30 includes an X-ray source 32 configured to irradiate a target 34, such as a human patient with X-ray radiation, an organic X-ray detector 36 as described earlier, and a processor 38 operable to process data from the organic x-ray detector 36. The X-ray source 32 may be a low-energy source to be employed in low energy imaging techniques, such as fluoroscopic techniques. A collimator may be positioned adjacent to the X-ray source to permit a stream of X-ray radiation 31 emitted by the X-ray source 32 to radiate towards the target 34. A portion of the X-ray radiation is attenuated by the target 34 and at least some attenuated radiation impacts the detector 36.

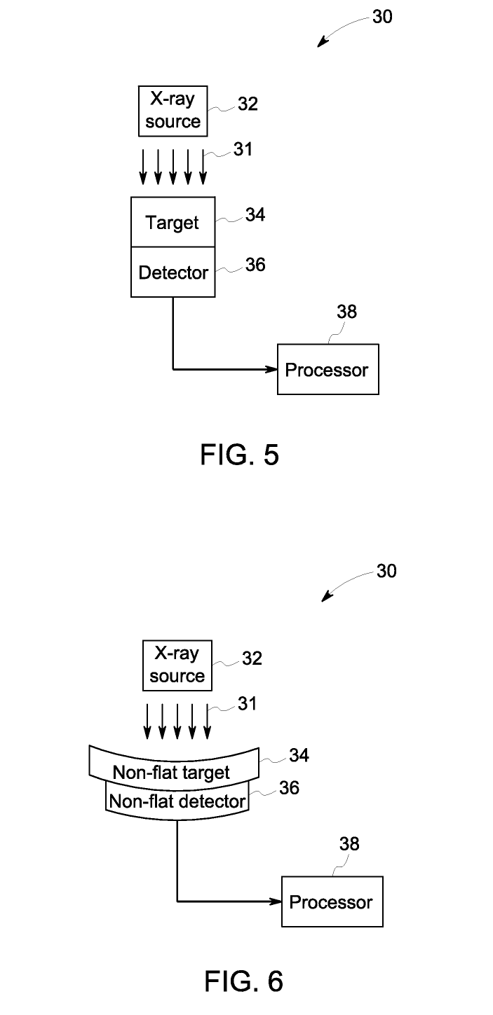

FIGS. 5 and 6 further show embodiments of the x-ray system 30 suitable for substantially flat objects or objects with a curved shape. As shown in FIGS. 5 and 6, the organic X-ray detector 36 may have a shape suitable for the target 34. The processor 38 may be communicatively coupled to the X-ray detector 36 using a wired or a wireless connection.

As described, the organic X-ray detector 36 is based on scintillation. A scintillator-based detector converts X-ray photons incident on its surface to optical photons. These optical photons may then be converted to electrical signals by employing photosensor(s), e.g., photodiode(s). These electrical signals are acquired and processed to construct an image of the features (e.g., anatomy) within the target 34. The processor 38 may include an image processing circuitry configured to receive acquired projection data from the detector 36. The image processing circuitry may be configured to process the acquired data to generate one or more images based on X-ray attenuation.

The image processing circuitry may be in communication with an operator workstation such that the workstation may receive and display the output of the image processing circuitry on an output device, such as a display or printer. In general, displays, printers, operator workstations, and similar devices supplied within the system may be local to the data acquisition components or may be remote from these components, such as elsewhere within an institution or hospital or in an entirely different location. Output devices and operator workstations that are remote from the data acquisition components may be operatively coupled to the image acquisition system via one or more configurable networks, such as the internet, virtual private networks, and so forth. As will be appreciated by one of ordinary skill in the art, the system controller, image processing circuitry, and operator workstation may actually be embodied in a single processor-based computing system. Alternatively, some or all of these components may be present in distinct processor-based computing systems configured to communicate with one another.

An x-ray detector according to embodiments of the present invention may be used in conformal imaging, with the detector in intimate contact with the imaging surface. For parts with internal structure, the detector may be rolled or shaped to contact the part being imaged. Applications for flexible, light-weight, highly rugged detectors according to present invention include security and medical imaging, and industrial and military imaging for pipeline, fuselage, airframe and other tight access areas.

### DEFINITIONS

As used herein, the term “aromatic radical” refers to an array of atoms having a valence of at least one comprising at least one aromatic group. The array of atoms having a valence of at least one comprising at least one aromatic group may include heteroatoms such as nitrogen, sulfur, selenium, silicon and oxygen, or may be composed exclusively of carbon and hydrogen. As used herein, the term “aromatic radical” includes but is not limited to phenyl, pyridyl, furanyl, thienyl, naphthyl, phenylene, and biphenyl radicals. As noted, the aromatic radical contains at least one aromatic group. The aromatic group is invariably a cyclic structure having 4n+2 “delocalized” electrons where “n” is an integer equal to 1 or greater, as illustrated by phenyl groups (n=1), thienyl groups (n=1), furanyl groups (n=1), naphthyl groups (n=2), azulenyl groups (n=2), and anthraceneyl groups (n=3). The aromatic radical may also include nonaromatic components. For example, a benzyl group is an aromatic radical which comprises a phenyl ring (the aromatic group) and a methylene group (the nonaromatic component). Similarly a tetrahydronaphthyl radical is an aromatic radical comprising an aromatic group (C₆H₃) fused to a nonaromatic component —(CH₂)₄—. For convenience, the term “aromatic radical” is defined herein to encompass a wide range of functional groups such as alkyl groups, alkenyl groups, alkynyl groups, haloalkyl groups, haloaromatic groups, conjugated dienyl groups, alcohol groups, ether groups, aldehydes groups, ketone groups, carboxylic acid groups, acyl groups (for example carboxylic acid derivatives such as esters and amides), amine groups, nitro groups, and the like. For example, the 4-methylphenyl radical is a C₇ aromatic radical comprising a methyl group, the methyl group being a functional group which is an alkyl group. Similarly, the 2-nitrophenyl group is a C₆ aromatic radical comprising a nitro group, the nitro group being a functional group. Aromatic radicals include halogenated aromatic radicals such as 4-trifluoromethylphenyl, hexafluoroisopropylidenebis(4-phen-1-yloxy) (i.e., —OPhC(CF₃)₂PhO—), 4-chloromethylphen-1-yl, 3-trifluorovinyl-2-thienyl, 3-trichloro methylphen-1-yl (i.e., 3-CCl₃Ph-), 4-(3-bromoprop-1-yl)phen-1-yl (i.e., 4-BrCH₂CH₂CH₂Ph-), and the like. Further examples of aromatic radicals include 4-allyloxyphen-1-oxy, 4-aminophen-1-yl (i.e., 4-H₂NPh-), 3-aminocarbonylphen-1-yl (i.e., NH₂COPh-), 4-benzoylphen-1-yl, dicyanomethylidenebis(4-phen-1-yloxy) (i.e., —OPhC(CN)₂PhO—), 3-methylphen-1-yl, methylenebis(4-phen-1-yloxy) (i.e., —OPhCH₂PhO—), 2-ethylphen-1-yl, phenylethenyl, 3-formyl-2-thienyl, 2-hexyl-5-furanyl, hexamethylene-1,6-bis(4-phen-1-yloxy) (i.e., —OPh(CH₂)₆PhO—), 4-hydroxymethylphen-1-yl (i.e., 4-HOCH₂Ph-), 4-mercaptomethylphen-1-yl (i.e., 4-HSCH₂Ph-), 4-methylthiophen-1-yl (i.e., 4-CH₃SPh-), 3-methoxyphen-1-yl, 2-methoxycarbonylphen-1-yloxy (e.g. methyl salicyl), 2-nitromethylphen-1-yl (i.e., 2-NO₂CH₂Ph), 3-trimethylsilylphen-1-yl, 4-t-butyldimethylsilylphenl-1-yl, 4-vinylphen-1-yl, vinylidenebis(phenyl), and the like. The term “a C₃-C₂₀ aromatic radical” includes aromatic radicals containing at least three but no more than 20 carbon atoms. The aromatic radical 1-imidazolyl (C₃H₂N₂—) represents a C₃ aromatic radical. The benzyl radical (C₇H₇—) represents a C₇ aromatic radical.

As used herein the term “cycloaliphatic radical” refers to a radical having a valence of at least one, and comprising an array of atoms which is cyclic but which is not aromatic. As defined herein a “cycloaliphatic radical” does not contain an aromatic group. A “cycloaliphatic radical” may comprise one or more noncyclic components. For example, a cyclohexylmethyl group (C₆H₁₁CH₂—) is an cycloaliphatic radical which comprises a cyclohexyl ring (the array of atoms which is cyclic but which is not aromatic) and a methylene group (the noncyclic component). The cycloaliphatic radical may include heteroatoms such as nitrogen, sulfur, selenium, silicon and oxygen, or may be composed exclusively of carbon and hydrogen. For convenience, the term “cycloaliphatic radical” is defined herein to encompass a wide range of functional groups such as alkyl groups, alkenyl groups, alkynyl groups, haloalkyl groups, conjugated dienyl groups, alcohol groups, ether groups, aldehyde groups, ketone groups, carboxylic acid groups, acyl groups (for example carboxylic acid derivatives such as esters and amides), amine groups, nitro groups, and the like. For example, the 4-methylcyclopent-1-yl radical is a C₆ cycloaliphatic radical comprising a methyl group, the methyl group being a functional group which is an alkyl group. Similarly, the 2-nitrocyclobut-1-yl radical is a C₄ cycloaliphatic radical comprising a nitro group, the nitro group being a functional group. A cycloaliphatic radical may comprise one or more halogen atoms which may be the same or different. Halogen atoms include, for example; fluorine, chlorine, bromine, and iodine. Cycloaliphatic radicals comprising one or more halogen atoms include 2-trifluoromethylcyclohex-1-yl, 4-bromodifluoromethylcyclooct-1-yl, 2-chlorodifluoromethylcyclohex-1-yl, hexafluoroisopropylidene-2,2-bis(cyclohex-4-yl) (i.e., —C₆H¹⁰C(CF₃)₂C₆H₁₀—), 2-chloromethylcyclohex-1-yl, 3-difluoromethylenecyclohex-1-yl, 4-trichloromethylcyclohex-1-yloxy, 4-bromodichloromethylcyclohex-1-ylthio, 2-bromoethylcyclopent-1-yl, 2-bromopropylcyclohex-1-yloxy (e.g. CH₃CHBrCH₂C₆H₁₀O—), and the like. Further examples of cyclo aliphatic radicals include 4-allyloxycyclohex-1-yl, 4-aminocyclohex-1-yl (i.e., H₂C₆H₁₀—), 4-aminocarbonylcyclopent-1-yl (i.e. NH₂COC₅H⁸—), 4-acetyloxycyclohex-1-yl, 2,2-dicyanoisopropylidenebis(cyclohex-4-yloxy) (i.e., —OC₆H₁₀C(CN)₂C₆H₁₀O—), 3-methylcyclohex-1-yl, methylenebis(cyclohex-4-yloxy) (i.e., —OC₆H₁₀CH₂C₆H₁₀O—), 1-ethylcyclobut-1-yl, cyclopropylethenyl, 3-formyl-2-terahydrofuranyl, 2-hexyl-5-tetrahydrofuranyl, hexamethylene-1,6-bis(cyclohex-4-yloxy) (i.e., —OC₆H₁₀(CH₂)₆C₆H₁₀O—), 4-hydroxymethylcyclohex-1-yl (i.e., 4-HOCH₂C₆H₁₀—), 4-mercaptomethylcyclohex-1-yl (i.e., 4-HSCH₂C₆H₁₀—), 4-methylthiocyclohex-1-yl (i.e., 4-CH₃SC₆H₁₀—), 4-methoxycyclohex-1-yl, 2-methoxycarbonylcyclohex-1-yloxy(2-CH₃OCOC₆H₁₀O—), 4-nitromethylcyclohex-1-yl (i.e., NO₂CH₂C₆H₁₀—), 3-trimethylsilylcyclohex-1-yl, 2-t-butyldimethylsilylcyclopent-1-yl, 4-trimethoxysilylethylcyclohex-1-yl (e.g. (CH₃O)₃SiCH₂CH₂C₆H₁₀—), 4-vinylcyclohexen-1-yl, vinylidenebis(cyclohexyl), and the like. The term “a C₃-C₁₀ cycloaliphatic radical” includes cycloaliphatic radicals containing at least three but no more than 10 carbon atoms. The cycloaliphatic radical 2-tetrahydrofuranyl (C₄H₇O—) represents a C₄ cycloaliphatic radical. The cyclohexylmethyl radical (C₆H₁₁CH₂—) represents a C₇ cycloaliphatic radical.

As used herein the term “aliphatic radical” refers to an organic radical having a valence of at least one consisting of a linear or branched array of atoms which is not cyclic. Aliphatic radicals are defined to comprise at least one carbon atom. The array of atoms comprising the aliphatic radical may include heteroatoms such as nitrogen, sulfur, silicon, selenium and oxygen or may be composed exclusively of carbon and hydrogen. For convenience, the term “aliphatic radical” is defined herein to encompass, as part of the “linear or branched array of atoms which is not cyclic” organic radicals substituted with a wide range of functional groups such as alkyl groups, alkenyl groups, alkynyl groups, haloalkyl groups, conjugated dienyl groups, alcohol groups, ether groups, aldehyde groups, ketone groups, carboxylic acid groups, acyl groups (for example carboxylic acid derivatives such as esters and amides), amine groups, nitro groups, and the like. For example, the 4-methylpent-1-yl radical is a C₆ aliphatic radical comprising a methyl group, the methyl group being a functional group which is an alkyl group. Similarly, the 4-nitrobut-1-yl group is a C₄ aliphatic radical comprising a nitro group, the nitro group being a functional group. An aliphatic radical may be a haloalkyl group which comprises one or more halogen atoms which may be the same or different. Halogen atoms include, for example; fluorine, chlorine, bromine, and iodine. Aliphatic radicals comprising one or more halogen atoms include the alkyl halides trifluoromethyl, bromodifluoromethyl, chlorodifluoromethyl, hexafluoroisopropylidene, chloromethyl, difluorovinylidene, trichloromethyl, bromodichloromethyl, bromoethyl, 2-bromotrimethylene (e.g. 13 CH₂CHBrCH₂—), and the like. Further examples of aliphatic radicals include allyl, aminocarbonyl (i.e., —CONH₂), carbonyl, 2,2-dicyanoisopropylidene (i.e., —CH₂C(CN)₂CH₂—), methyl (i.e., —CH₃), methylene (i.e., —CH₂—), ethyl, ethylene, formyl (i.e. —CHO), hexyl, hexamethylene, hydroxymethyl (i.e. —CH₂OH), mercaptomethyl (i.e., —CH₂SH), methylthio (i.e., —SCH₃), methylthiomethyl (i.e., —CH₂SCH₃), methoxy, methoxycarbonyl (i.e., CH₃OCO—), nitromethyl (i.e., —CH₂NO₂), thiocarbonyl, trimethylsilyl (i.e., (CH₃)₃Si—), t-butyldimethylsilyl, 3-trimethyoxysilypropyl (i.e., (CH₃O)₃SiCH₂CH₂CH₂—), vinyl, vinylidene, and the like. By way of further example, a C₁-C₂₀ aliphatic radical contains at least one but no more than 20 carbon atoms. A methyl group (i.e., CH₃—) is an example of a C₁ aliphatic radical. A decyl group (i.e., CH₃((CH₂)₉—) is an example of a C₁₀ aliphatic radical.

The term “heteroaryl” as used herein refers to aromatic or unsaturated rings in which one or more carbon atoms of the aromatic ring(s) are replaced by a heteroatom(s) such as nitrogen, oxygen, boron, selenium, phosphorus, silicon or sulfur. Heteroaryl refers to structures that may be a single aromatic ring, multiple aromatic ring(s), or one or more aromatic rings coupled to one or more non-aromatic ring(s). In structures having multiple rings, the rings can be fused together, linked covalently, or linked to a common group such as an ether, methylene or ethylene moiety. The common linking group may also be a carbonyl as in phenyl pyridyl ketone. Examples of heteroaryl rings include thiophene, pyridine, isoxazole, pyrazole, pyrrole, furan, imidazole, indole, thiazole, benzimidazole, quinoline, isoquinoline, quinoxaline, pyrimidine, pyrazine, tetrazole, triazole, benzo-fused analogues of these groups, benzopyranone, phenylpyridine, tolylpyridine, benzothienylpyridine, phenylisoquinoline, dibenzoquinozaline, fluorenylpyridine, ketopyrrole, 2-phenylbenzoxazole, 2 phenylbenzothiazole, thienylpyridine, benzothienylpyridine, 3 methoxy-2-phenylpyridine, phenylimine, pyridylnaphthalene, pyridylpyrrole, pyridylimidazole, and phenylindole.

The term “aryl” is used herein to refer to an aromatic substituent which may be a single aromatic ring or multiple aromatic rings which are fused together, linked covalently, or linked to a common group such as an ether, methylene or ethylene moiety. The aromatic ring(s) may include phenyl, naphthyl, anthracenyl, and biphenyl, among others. In particular embodiments, aryls have between 1 and 200 carbon atoms, between 1 and 50 carbon atoms or between 1 and 20 carbon atoms.

The term “alkyl” is used herein to refer to a branched or unbranched, saturated or unsaturated acyclic hydrocarbon radical. Suitable alkyl radicals include, for example, methyl, ethyl, n-propyl, i-propyl, 2-propenyl (or allyl), vinyl, n-butyl, t-butyl, i-butyl (or 2-methylpropyl), etc. In particular embodiments, alkyls have between 1 and 200 carbon atoms, between 1 and 50 carbon atoms or between 1 and 20 carbon atoms.

The term “cycloalkyl” is used herein to refer to a saturated or unsaturated cyclic non-aromatic hydrocarbon radical having a single ring or multiple condensed rings. Suitable cycloalkyl radicals include, for example, cyclopentyl, cyclohexyl, cyclooctenyl, bicyclooctyl, etc. In particular embodiments, cycloalkyls have between 3 and 200 carbon atoms, between 3 and 50 carbon atoms or between 3 and 20 carbon atoms.

Any numerical values recited herein include all values from the lower value to the upper value in increments of one unit provided that there is a separation of at least 2 units between any lower value and any higher value. As an example, if it is stated that the amount of a component or a value of a process variable such as, for example, temperature, pressure, time and the like is, for example, from 1 to 90, preferably from 20 to 80, more preferably from 30 to 70, it is intended that values such as 15 to 85, 22 to 68, 43 to 51, 30 to 32 etc. are expressly enumerated in this specification. For values which are less than one, one unit is considered to be 0.0001, 0.001, 0.01 or 0.1 as appropriate. These are only examples of what is specifically intended and all possible combinations of numerical values between the lowest value and the highest value enumerated are to be considered to be expressly stated in this application in a similar manner.

### EXAMPLES

PolyTPD (ADS254BE), MEH-PPV (ADS100RE) and F8TFB (ADS259BE) were purchased from American Dye Source, Inc. PCDTBT and PTB7 were obtained from 1-Materials, Inc, Quebec, Canada. The purchased materials were received and then stored in a nitrogen box until they were processed into thin films.

PolyTPD: Poly[N,N′-bis(4-butylphenyl)-N,N′-bis(phenyl)-benzidine]

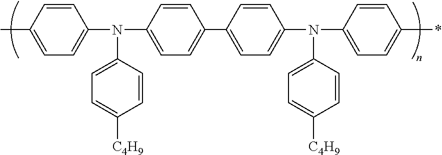

PCDTBT: Poly[N-9′-heptadecanyl-2,7-carbazole-alt-5,5-(4′,7′-di-2-thienyl-2′,1′,3′-benzothiadiazole)]

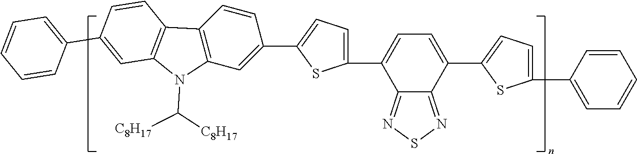

PTB-7: Poly{4,8-bis[(2-ethylhexyl)oxy]benzo[1,2-b:4,5-b′]dithiophene-2,6-diyl-alt-3-fluoro-2-[(2-ethylhexyl)carbonyl]thieno[3,4-b]thiophene-4,6-diyl}

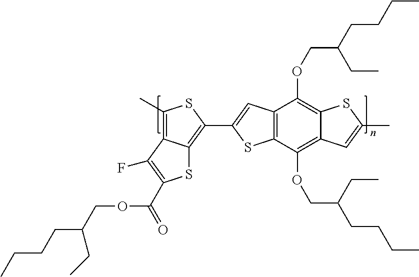

F8TFB: Poly[(9,9-dioctylfluorenyl-2,7-diyl)-co-(4,4′-(N-(p-butylphenyl)) diphenylamine)]

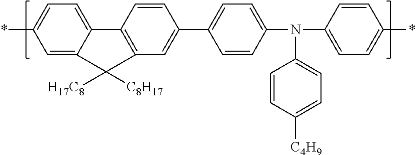

MEH-PPV: Poly[2-methoxy-5-(2-ethylhexyloxy)-1,4-phenylene-vinylene]

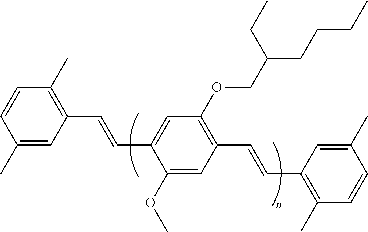

### Example 1

Wash-off Test for Composite Leakage Reduction Layers

Various samples were prepared by using conjugate polymers: polyTPD, PCDTBT, PTB-7, MEH-PPV and F8TFB.

Comparative Samples 1-5

For the fabrication of a sample (Comparative samples 1), a 0.5 w/v % solution of polyTPD was prepared by dissolving 35 mg of polyTPD in 3.0 ml chlorobenzene. A thin film (80 nm in thickness) of polyTPD was then obtained by spin-coating the solution on a pre-cleaned glass substrate. The resulting film was baked at 160° C. for 3 minutes, and then cured by exposure to UV radiation for 2 minutes followed by baking for 30 minutes. Additional samples (Comparative samples 2-5, Table 1) of PCDTBT, PTB-7, MEH-PPV and F8TFB, were prepared in similar manner as described for comparative sample 1. All the samples were then rinsed with chlorobenzene.

Experimental Samples 1-7

Compound 1 was obtained from Konica Minolta Holdings, Inc., Tokyo, Japan; and an epoxy (ELC2500) was obtained from Electro-lite Corporation, Bethel, Conn., USA. For experimental sample 1, a mixture solution of polyTPD:compound 1 was prepared by mixing 35 mg of polyTPD and 25 mg of compound 1 in 3.0 ml chlorobenzene. A thin film (35 nm in thickness) of polyTPD:compound 1 was then obtained by spin-coating on a pre-cleaned glass substrate, which was then baked at 160° C. for 3 minutes and cured under UV radiation for 2 minutes, further baked at 160° C. for about 30 minutes. Additional samples (experimental samples 2-7, Table 1) using polyTPD:epoxy, PCDTBT:compound 1, PCDTBT:epoxy, PTB-7: compound 1, MEH-PPV:compound 1 and F8TFB:compound 1 were prepared in similar manner as described for the experimental sample 1. UV irradiation, for each sample, was carried out at 365 nanometers (nm) with a Blak-Ray UVL-56 365 nm ultraviolet lamp having an intensity of about 20 mW/cm² at the 365 nm wavelength under an atmosphere of nitrogen or air. All the samples were then rinsed with chlorobenzene (CB).

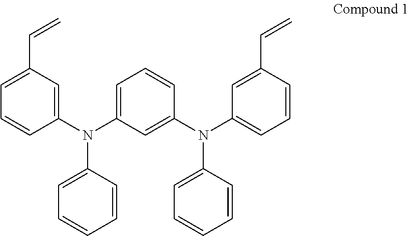 [SMILES: C=Cc1cccc(N(c2ccccc2)c2cccc(N(c3ccccc3)c3cccc(C=C)c3)c2)c1]

Table 1 shows the results of the wash-off test by rinsing the thin film samples by chlorobenzene. It is clear from Table 1 that more than 90% of the materials washed off by cholorobenze for the comparative samples 1-5 that were prepared without mixing compound 1 or epoxy with a conjugate polymer. Experimental samples 1-7 were prepared includes a combination of a conjugate polymer and compound 1 or an epoxy. For samples (experimental samples 1-4) that include a combination of polyTPD or PCDTBT and compound 1 or epoxy, table 1 clearly shows almost no or very little (<1%) material loss, indicating that the thin films of experimental samples 1-4 are not soluble in chlorobenzene. However, the samples (experimental samples 5-7) show high material losses by chlorobenzene.

TABLE 1

| | | Thickness loss after |
|---|---|---|
| Sample | Thin film Structure | rinsing with CB |
| Comparative sample 1 | polyTPD | 98% |
| Comparative sample 2 | PCDTBT | 93% |
| Comparative sample 3 | PTB-7 | 99% |
| Comparative sample 4 | MEV-PPV | 98% |
| Comparative sample 5 | F8TFB | 94% |
| Experimental sample 1 | polyTPD:compound 1 | <1% |
| Experimental sample 2 | polyTPD:epoxy | <1% |
| Experimental sample 3 | PCDTBT:compound 1 | <1% |
| Experimental sample 4 | PCDTBT:epoxy | <1% |
| Experimental sample 5 | PTB-7: compound 1 | 67% |
| Experimental sample 6 | MEH-PPV:compound 1 | 88% |
| Experimental sample 7 | F8TFB:compound 1 | 78% |

### Example 2

Organic Photodiodes With and Without Composite Leakage Reduction Layer

Bulk heterojunction organic photodiodes devices were fabricated using a fullerene as the electron acceptor and PCDTBT or PTB7 as the electron donor for the absorber layer. Four organic photodiodes devices (OPDs) were fabricated as follows: two OPDs were fabricated without a composite leakage reduction layer and two OPDs were fabricated with a composite leakage reduction layer.

Absorber blends were prepared in the nitrogen glovebox by dissolving the donor PCDTBT and PTB7 respectively with a fullerene based acceptor at a 1:1 weight ratio at 20-80 mg/mL into 1,2-dichlorobenzene. A mixture solution of polyTPD:compound 1 was prepared as described with respect to Experimental sample 1 in example 1 for a composite leakage reduction layer.

Two control OPD devices 1 and 2 were fabricated. Glass pre-coated with ITO was used as the substrate. An 80 nm layer of composite leakage reduction layer consisting of polyTPD:compound 1 was deposited onto the ITO substrate via spin-coating and then UV cured and baked for 1 hour at 180° C. in air. An absorber layer consisting of a fullerene based acceptor and a donor polymer, PCDTBT and PTB7, was then spin-coated atop the composite leakage reduction layer inside of a N₂ purged glovebox for the control device 1. A bilayer cathode consisting of 3.5 nm of Ca was deposited, followed by 100 nm of Al. The device fabrication was completed with ITO sputtering. For control device 2, an absorber layer consisting of a fullerene based acceptor and a donor polymer, PTB-7 was spin-coated atop the composite leakage reduction. Two comparative OPD devices were fabricated in the similar manner with the exception of the composite leakage reduction layer deposition. The device performance was characterized by measuring current-voltage (I-V) characteristics.

Table 2 summarizes the results for OPDs fabricated with and without the composite leakage reduction layers. As one can see in Table 2, the control devices 1 and 2 including the composite leakage reduction layer exhibit significantly lower leakage current (˜10 percent) relative to the leakage current of the corresponding comparative devices 1 and 2. A low leakage current in an OPD is beneficial for the overall photodiode performance.

TABLE 2
Performance of OPDs with and without composite
leakage reduction layer (polyTPD:compound 1)

| | | Donor polymer | |
|---|---|---|---|
| | Composite leakage | (Absorber | Leakage Current |
| Sample | reduction layer | layer) | (nA/cm²) |
| Comparative | | PCDTBT | 0.3 |
| device 1 | | | |
| Control | polyTPD:compound 1 | PCDTBT | 0.02 |
| Device 1 | | | |
| Comparative | | PTB-7 | 43 |
| Device 2 | | | |
| Control | polyTPD:compound 1 | PTB-70 | 4.9 |
| Device 2 | | | |

### Example 3

Performance of Organic X-ray Detector Imagers With and Without the Composite Leakage Reduction Layer

Two organic x-ray imagers based on the organic photodiode (OPD) technology were fabricated as follows:

Glass based thin-film-transistor (TFT) array pre-coated with ITO was used as the substrate. An 80 nm layer of composite leakage reduction layer consisting of polyTPD:compound 1 was deposited onto the TFT substrate via spin-coating and then UV cured and baked for 1 hour at 180° C. in air. An absorber layer consisting of a fullerene based acceptor and a donor material, PCDTBT was then spin-coated atop the composite leakage reduction layer inside of a N₂ purged glovebox. The comparative imager fabrication was completed with ITO sputtering. The device performance was characterized using an imager functional tester. A control imager was fabricated in a similar fashion except for the deposition of the composite leakage reduction layer.

TABLE 3
Performance of organic X-ray detector imagers

| | Composite leakage | Cluster type | Leakage Current |
|---|---|---|---|
| Sample | reduction layer | defect | (pA/cm²) |
| Comparative | | 3 | 21.5 |
| imager | | | |
| Control | polyTPD:compound 1 | 0 | 7.8 |
| imager | | | |

As it is clear from Table 3, the OXRD control imager exhibits significantly reduced number of cluster-type defects and reduced dark leakage current as compared to the comparative imager, which are two key aspects of a functional detector.

The foregoing examples are merely illustrative, serving to exemplify only some of the features of the invention. The appended claims are intended to claim the invention as broadly as it has been conceived and the examples herein presented are illustrative of selected embodiments from a manifold of all possible embodiments.

Accordingly, it is the Applicants' intention that the appended claims are not to be limited by the choice of examples utilized to illustrate features of the present invention. As used in the claims, the word “comprises” and its grammatical variants logically also subtend and include phrases of varying and differing extent such as for example, but not limited thereto, “consisting essentially of” and “consisting of.” Where necessary, ranges have been supplied; those ranges are inclusive of all sub-ranges there between. It is to be expected that variations in these ranges will suggest themselves to a practitioner having ordinary skill in the art and where not already dedicated to the public, those variations should where possible be construed to be covered by the appended claims. It is also anticipated that advances in science and technology will make equivalents and substitutions possible that are not now contemplated by reason of the imprecision of language and these variations should also be construed where possible to be covered by the appended claims.

1. An organic x-ray detector having a layered structure comprising:
a thin film transistor (TFT) array disposed on a substrate;
a first electrode disposed on the TFT array;
a leakage reduction layer disposed on the first electrode, wherein the leakage reduction layer comprises a conjugate polymer and a crosslinkable compound;
an absorber layer comprising an acceptor material and a donor material disposed on the leakage reduction layer, wherein the acceptor material comprises fullerene or a fullerene derivative;
a second electrode disposed on the absorber layer; and
a scintillator layer disposed on the second electrode.

2. The organic x-ray detector according to claim 1, wherein the conjugate polymer comprises a polytriarylamine, a poly(para-phenylene), a poly(N-vinylcarbazole), a polyfluorene, a poly(p-phenylene vinylene), copolymers thereof, or a combination thereof.

3. The organic x-ray detector according to claim 2, wherein the polytriarylamine comprises structural units of formula I

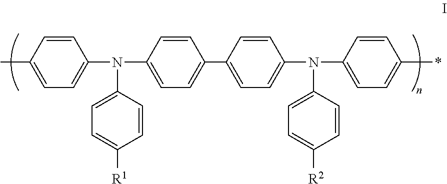

4. The organic x-ray detector according to claim 1, wherein the crosslinkable compound comprises at least one functional group selected from arylamine and arylphosphine, and at least two functional groups selected from vinyl, allyl, vinyl ether, epoxy, and acrylate.

5. The organic x-ray detector according to claim 1, wherein the crosslinkable compound comprises an epoxy.

6. The organic x-ray detector according to claim 1, wherein the crosslinkable compound is of formula II 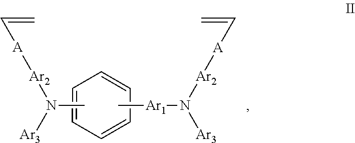
wherein
Ar₁ is direct bond, an aryl or heteroaryl;
Ar₂ and Ar₃ are independently at each occurrence, an aryl or heteroaryl; and
A is independently at each occurrence, O or a direct bond.

7. The organic x-ray detector according to claim 6, wherein the crosslinkable compound is selected from

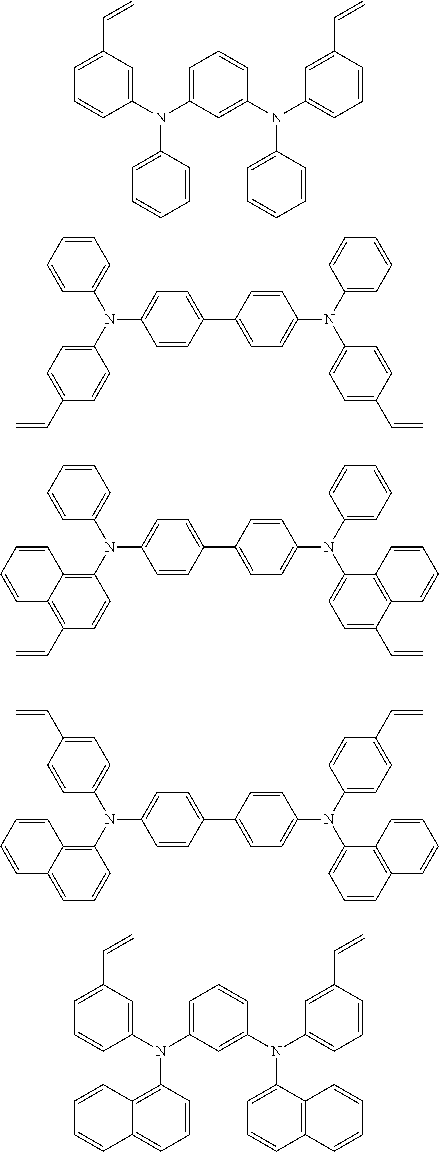

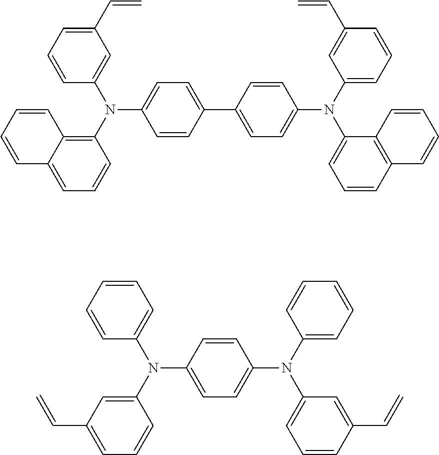 [SMILES: C=Cc1cccc(N(c2ccc(-c3ccc(N(c4cccc(C=C)c4)c4cccc5ccccc45)cc3)cc2)c2cccc3ccccc23)c1 ; C=Cc1cccc(N(c2ccccc2)c2ccc(N(c3ccccc3)c3cccc(C=C)c3)cc2)c1]

8-9. (canceled)

10. The organic x-ray detector according to claim 1, wherein the donor material comprises a low bandgap polymer having a HOMO greater than or equal to 5.0 eV.

11. The organic x-ray detector according to claim 10, wherein the low band gap polymer comprises units derived from substituted or unsubstituted thienothiophene, benzodithiophene, benzothiadiazole, pyrrolothiophene, carbazole, or a combinations thereof.

12. The organic x-ray detector according to claim 10, wherein the donor material comprises a conjugate polymer that is used in a leakage reduction layer.

13. The organic x-ray detector according to claim 1, further comprising an additional leakage reduction layer disposed between the absorber layer and the second electrode.

14. A process for fabricating an organic x-ray detector, the process comprising:
disposing a leakage reduction layer comprising a conjugate polymer and a crosslinkable compound on a first electrode of a TFT array disposed on a substrate,
disposing an absorber layer from a solution of an accepter material and a donor material with a first solvent selected from chlorobenzene, dichlorobenzene or a mixture thereof, wherein the acceptor material comprises fullerene or a fullerene derivative;
disposing a second electrode layer on the absorber layer; and
disposing a scintillator layer on the second electrode layer.

15. The process according to claim 14, wherein the step of disposing the leakage reduction layer comprises forming a layer from a mixture solution of the conjugate polymer and the crosslinkable polymer with a second solvent.

16. The process according to claim 15, wherein the step of disposing the leakage reduction layer further comprises exposing the layer to heat, a radiation source or a combination thereof.

17. The process according to claim 14, wherein the step of disposing the absorber layer comprises disposing the absorber layer by solvent casting, spin coating, dip coating, spray coating, blade coating, or combinations thereof.

18. The process according to claim 14, wherein the conjugate polymer comprises a polytriarylamine, a poly(para-phenylene), a poly(N-vinylcarbazole), a polyfluorene, a poly(p-phenylene vinylene), copolymers thereof, or combinations thereof.

19. The process according to claim 14, wherein the conjugate polymer comprises polytriarylamine having structural units of formula I

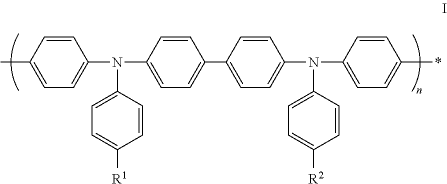

20. The process according to claim 14, wherein the crosslinkable compound comprises at least one functional group selected from the group consisting of arylamine and arylphosphine, and at least two functional groups selected from the group consisting of vinyl, allyl, vinyl ether, epoxy, and acrylate.

21. The process according to claim 14, wherein the crosslinkable compound is

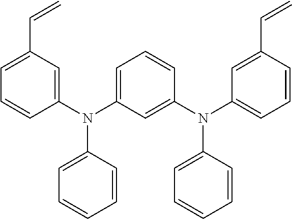 [SMILES: C=Cc1cccc(N(c2ccccc2)c2cccc(N(c3ccccc3)c3cccc(C=C)c3)c2)c1]

22. An x-ray imaging system comprising an x-ray source, the organic x-ray detector in accordance with claim 1, and a processor operable to process data from the organic x-ray detector.
